(19) United States
(12) Patent Application Publication
(10) Pub. No.: US 2010/0321060 A1
(43) Pub. Date: Dec. 23, 2010

(54) SEMICONDUCTOR LSI AND SEMICONDUCTOR DEVICE

(75) Inventors: Yoji Nishio, Tokyo (JP); Yutaka Uematsu, Kanagawa (JP); Hideki Oosaka, Kanagawa (JP); Akihiro Namba, Kanagawa (JP); Satoshi Nakamura, Kanagawa (JP)

Correspondence Address: YOUNG & THOMPSON, 209 Madison Street, Suite 500, Alexandria, VA, 22314, US

(73) Assignee: ELPIDA MEMORY, INC., Tokyo (JP)

(21) Appl. No.: 12/816,684

(22) Filed: Jun. 16, 2010

(30) Foreign Application Priority Data
Jun. 17, 2009 (JP) 2009-144111

(51) Int. Cl. H03K 19/003

(52) U.S. Cl. 326/30

(57) ABSTRACT

In a signal transmission system, performing signal transmission via signal interconnections 4-1 to 4-3 between a memory 1 and a memory controller 2 mounted on a printed circuit board 3, noise or jitter may tend to be increased in the memory 1 and in the memory controller 2 at a specified data rate due to interconnection length resonance. Registers 6-1 and 6-2 are provided to hold information on the data rate. These registers 6-1 and 6-2 are provided in the signal transmission system along with a control system that modifies the relationship between clock frequency and interconnection length. The data rate or the propagation delay time is controlled to allow for avoiding the resonance.

### CROSS-REFERENCE TO RELATED APPLICATION

This application is based upon and claims the benefit of the priority of Japanese patent application No. 2009-144111 filed on Jun. 17, 2009, the disclosure of which is incorporated herein in its entirety by reference thereto.

This invention relates to a semiconductor device. More particularly, it relates to a technique applicable with advantage to a plurality of semiconductor LSI circuits (Large Scaled Integrated Circuits), a signal transmission system that has the semiconductor LSI circuits mounted on a printed circuit board, and to a semiconductor device comprised of this signal transmission system mounted within a housing.

### TECHNICAL FIELD

### Background

In a semiconductor device, the tendency is towards a higher data rate and a lower voltage in order to keep pace with the evolution of semiconductor LSI generations. As a result, the problem connected with signal noise, power supply noise and jitter (timing variations of signals) consequent thereon is becoming more apparent. In particular, the wavelength of the transmit signal has become of the same order of magnitude as the length of the interconnection on a printed circuit board (PCB). For this reason, the noise or jitter tends to be increased acutely due to interconnection length resonance caused by reciprocations of the noise reflection on the interconnection, thus presenting a problem that needs to be eliminated.

To counter such problem, it is proposed in, for example, Patent Document 1 to set the distance between the sites of non-matched impedance on the transmitting and receiving sides so as to be equal to an integer number times half of a signal switching period in terms of the transmission time, in an attempt to overcome the problem of acute increase of jitter due to resonance.

[Patent Document 1] JP Patent Kokai Publication No. JP-P2001-111408A

### SUMMARY

The entire disclosure of the above patent document is incorporated herein by reference thereto. The following analysis is given by the present inventor.

In the technique of the above mentioned Patent Document 1, there are cases where the relationship between the interconnection length and the wavelength of the transmitted signal is changed due to change in the clocks in the BIOS setting that may be performed in commonplace personal computers. On the other hand, in the case of a semiconductor system, such a case may be presupposed where the signal data rate is changed during use of the system with a view to decreasing the power consumption. Taking a case of a memory bus, if, in a system usually operated at 800 Mbps, the volume of the information to be processed in the system is decreased, or a demand is raised for using a low power mode, there may arise a case where the system is used at a data rate decreased to 667 Mbps or even to 533 Mbps.

Viz., the phenomenon of resonance, which may be avoided by not using a specified wavelength in the case of a conventional semiconductor device (FIG. 2), may possibly not be avoided in the case of a system with a variable data rate. Thus there is much to be desired in the art.

It is therefore an object of the present invention to provide a technique according to which the noise or jitter ascribable to interconnection length resonance may be decreased even in a semiconductor device or a signal transmission system with a variable data rate.

Other objects and novel features of the present invention will become apparent from the following description and the drawings.

Representative aspects of the disclosures of the present Application may now be summarized as follows:

According to a first aspect of present disclosure, there is provided a plurality of semiconductor LSIs composing a signal transmission system setup (or formulation). There is also provided a semiconductor device constituting a signal transmission system that transmits signals via a plurality of signal interconnections between a plurality of semiconductor LSIs carried on a board. The semiconductor LSIs may be subjected to the noise or jitter which may be increased at a specified data rate due to interconnection length resonance. To cope with this situation, there is provided a register that holds information on the data rate. Further, reference is made to the data rate susceptible to the interconnection length resonance, via BIOS or a dip switch mounted on the board carrying (loading) the semiconductor LSIs, and the data rate, thus referenced, is held on the register.

More specifically, the data rate susceptible to resonance is set in advance in the register provided in the semiconductor LSIs composing a signal transmission system, such as in a memory. A processor controls an output clock signal of a clock generator to change the relationship between the system clock frequency and the interconnection length to avoid the current data rate from overlapping with the so set data rate. Viz., the memory includes the register to save the data rate for avoiding the resonance. There is provided a function of reading the information saved in the register to make fine adjustment in frequency selection at the time of generation of a system clock by a clock generator, thereby avoiding the wave length resonance.

The followings are some of meritorious effects that may be obtained by representative aspects of the present disclosure of the present application.

The noise or jitter ascribable to interconnection lengths may be reduced.

Since the signal quality may be improved by the noise or jitter reduction, it becomes possible to avoid malfunctions. Other features and advantages will become apparent from the entire disclosures including claims and drawings.

### BRIEF DESCRIPTION OF THE DRAWINGS

FIG. 1 shows an arrangement of a signal transmission system in an exemplary embodiment 1 of the present disclosure.

FIG. 2 shows an arrangement of a signal transmission system as a comparative example for illustrating the present invention.

FIG. 3 shows an arrangement of a signal transmission system in an exemplary embodiment 2 of the present disclosure.

FIG. 4 shows an arrangement of a signal transmission system in an exemplary embodiment 3 of the present disclosure.

FIG. 5 is a flowchart showing the processing flow for a sequence of specifying a data rate of interconnection length resonance of the crosstalk noise in the signal transmission system in the exemplary embodiment 3 of the present disclosure.

FIG. 6 illustrates the principle of occurrence of interconnection length resonance ascribable to the crosstalk noise in the signal transmission system in the exemplary embodiment 3 of the present disclosure.

FIG. 7 shows an arrangement of a signal transmission system in an exemplary embodiment 4 of the present disclosure.

FIG. 8 shows an arrangement of a signal transmission system in an exemplary embodiment 5 of the present disclosure.

FIG. 9 shows an arrangement of a signal transmission system in an exemplary embodiment 6 of the present disclosure.

FIG. 10 shows an arrangement of a signal transmission system in an exemplary embodiment 7 of the present disclosure.

FIG. 11 shows an arrangement of a signal transmission system in an exemplary embodiment 8 of the present disclosure.

FIG. 12 shows an arrangement of a signal transmission system in an exemplary embodiment 9 of the present disclosure.

### PREFERRED MODES

Certain preferred exemplary embodiments of the present disclosure will now be described in detail with reference to the drawings. In the total of the drawings, referred to for illustrating the exemplary embodiments, the same reference numerals are used as a principle to denote the same components, and the corresponding description for those same components is dispensed with.

Initially, to assist in understanding of the features of the present disclosure, a comparative example is referred to for comparison with the present invention. The description that follows is centered about a case of carrying out one-for-one DQ (data) signal transmission between a memory and a memory controller. It is noted however that the technique of the present disclosure may be applied to a wide variety of signal transmission systems without being restricted to signal transmission between the memory and the memory controller.

In the exemplary embodiments of the present disclosure, the memory and the memory controller, for example, are labeled a semiconductor LSI, and a set of the semiconductor LSIs, packaged on a printed circuit board, is labeled a signal transmission system. This signal transmission system, accommodated in a housing, is labeled a semiconductor device. In the following, the signal transmission system, accommodated in the semiconductor device, is mainly explained.

### (Discussion on the Comparative Example)

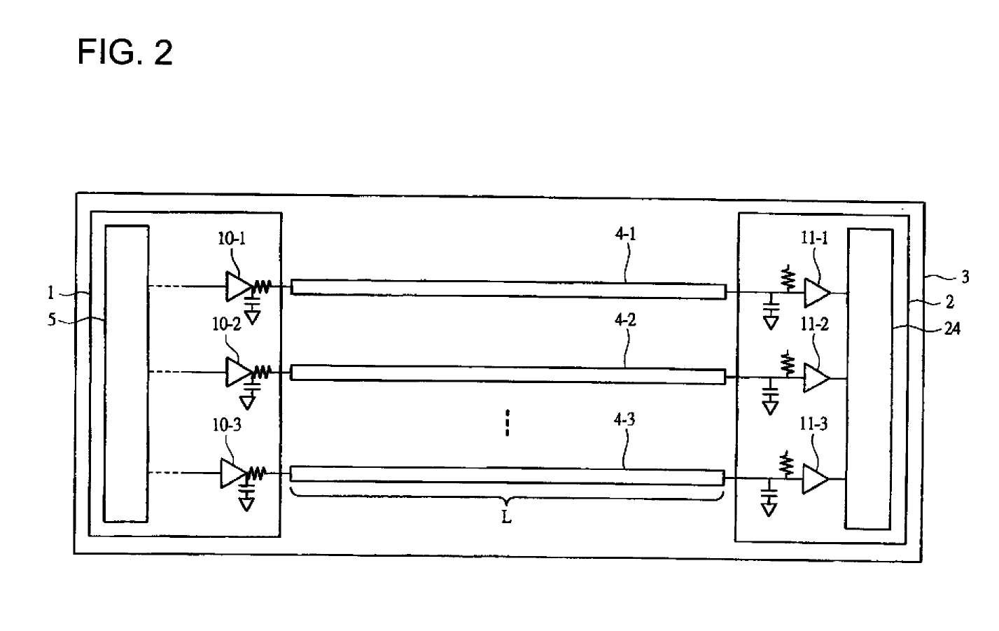

FIG. 2 shows an arrangement of a signal transmission system as a comparative example for illustrating the contrast to the present disclosure. In FIG. 2, the reference numerals 1, 2 and 3 denote a memory, such as DRAM or SRAM, a memory controller, and a printed circuit board (PCB), respectively. The reference numerals 4-1 to 4-3 denote signal interconnections on the PCB 3 interconnecting the memory and the memory controller. Within the memory 1, reference numeral 5 denotes an internal circuit which is DLL if the memory is a DRAM, or which is PLL if the memory is an SRAM. The reference numerals 10-1 to 10-3 denote driver circuits. Within the memory controller 2, reference numerals 11-1 to 11-3 denote receiver circuits, and reference numeral 24 denotes an internal circuit.

FIG. 2 shows a system of transmitting data from the memory 1 to the memory controller 2. In such system, capacitive reflection occurs at both ends of the signal interconnections 4-1 to 4-3 due to parasitic capacitances at the driver circuits 10-1 to 10-3 and to those at the receiver circuits 11-1 to 11-3. For this reason, the reflective noise travels back and forth on the signal interconnections 4-1 to 4-3 between the driver circuits 10-1 to 10-3 and the receiver circuits 11-1 to 11-3. At a specified data rate, the reflective noise generated by the previous data may coincide with that generated by the current data, in sign and timing, thus producing extremely large noise and jitter to give rise to a resonance-related problem. In the related technique, represented by the above mentioned Patent Document 1, the distance (L) on the interconnection between impedance non-matched sites on the sending and receiving sides is designed to a value that does not produce the resonance to avoid the problem of acute rise in jitter ascribable to the resonance.

However, in practical systems, an approximate value is set for the distance L. In addition, there is also a cross-talk related problem. Hence, the related technique may not be sufficient to cope with the situation. Moreover, with a variable data rate system, the design condition deviates from an optimum value as set in the related technique the instant the data rate has been changed, with the result that the problems may not be coped with.

In the exemplary embodiments of the present disclosure, the cross-talk related problem is also to be combated, and the technique, now described in detail, is used to reduce the interconnection length resonance related noise or jitter in addition to reducing the cross-talk. The present disclosure is also applicable to a data rate variable signal transmission system.

### Exemplary Embodiment 1

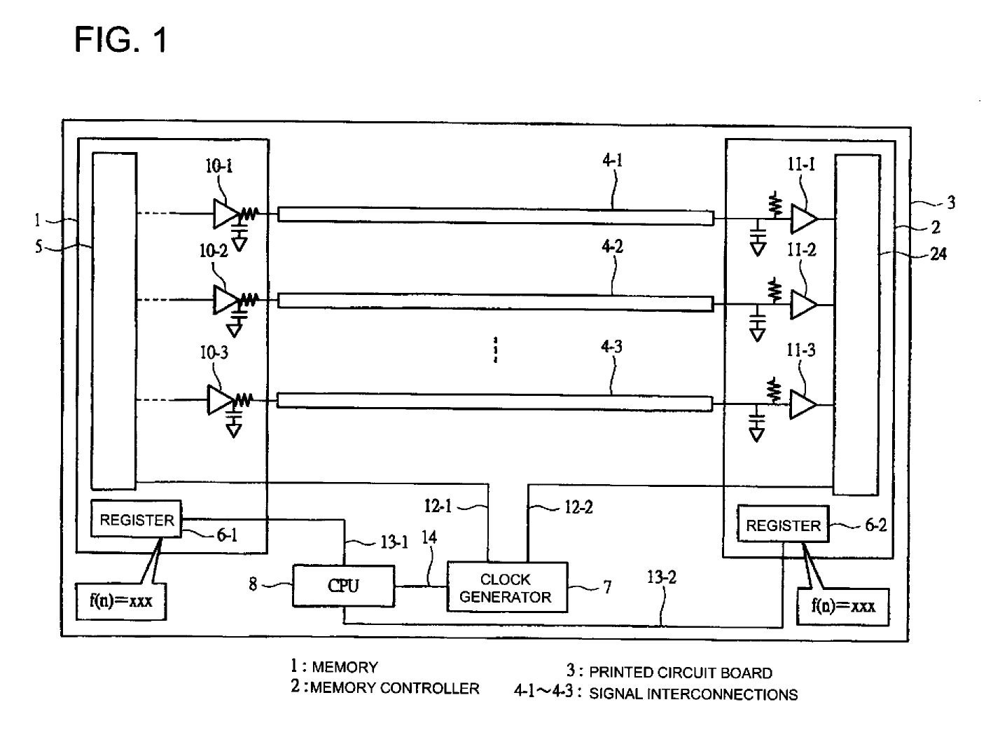

FIG. 1 shows an arrangement of a signal transmission system in an exemplary embodiment 1 of the present disclosure.

Initially, an arrangement of a signal transmission system in the present exemplary embodiment 1 will be described with reference to FIG. 1. The arrangement of the signal transmission system of the present exemplary embodiment is approximately the same as the conventional arrangement shown in FIG. 2, with the difference being that registers 6-1 and 6-2 are provided within the memory 1 or the memory controller 2 in the present exemplary embodiment.

That is, the signal transmission system in the present exemplary embodiment includes a memory 1, provided with an internal circuit 5 and a plurality of driver circuits 10-1 to 10-3, and a memory controller 2, provided with a plurality of receiver circuits 11-1 to 11-3 and an internal circuit 24. The signal transmission system also includes a printed circuit board 3 carrying thereon the memory 1 and the memory controller 2 and interconnecting the memory 1 and the memory controller 2 by a plurality of signal interconnections 4-1 to 4-3. The signal transmission system performs of signal transmission between the memory 1 and the memory controller 2, mounted on the printed circuit board 3, via the signal interconnections 4-1 to 4-3 placed on the printed circuit board 3. The registers 6-1 and 6-2 are provided within the memory 1 and the memory controller 2, respectively.

In addition to the memory 1 and the memory controller 2, a clock generator 7 and a CPU 8 are mounted on the printed circuit board 3. The clock generator 7 is connected via a clock interconnection 12-1 to the internal circuit 5 disclosed within the memory 1, while being connected via a clock interconnection 12-2 to the internal circuit 24 disclosed within the memory controller 2. The CPU 8 is connected via a register value readout signal interconnection 13-1 to the register 6-1 within the memory 1, while being connected via a register value readout signal interconnection 13-2 to the register 6-2 within the memory controller 2. The CPU 8 is also connected via a clock generator controlling signal interconnection 14 to the clock generator 7.

In the above arrangement, there is stored in the registers 6-1 and 6-2 the data rate related information for such case where the noise or jitter is increased as a result of interconnection length resonance at a specified data rate. The CPU 8, for example, reads out the information in order to dynamically change the data rate. The CPU has the function of controlling the clock generator 7 so that a data rate f(n) that leads to the interconnection length resonance will not be used on the occasion of dynamically changing the data rate. In the present description, this data rate is referred to below as a non-recommendable data rate.

It is noted that, in case the interconnection length resonance occurs at a specified data rate, it is necessary to change the period by at least 5% relative to the resonance period in order to avoid the resonance. Viz., if resonance occurs for a period 1 ns, that is, f(n)=1 Gbps, it is necessary to change the period by at least 5%, i.e., by at least 50 ps. Viz., it is sufficient to change the period to not higher than 0.95 ns or to not lower than 1.05 ns.

As a means for practically implementing the frequency change, a method of not using the non-recommendable data rate, or a method of changing the base clock of the clock generator or a multiplication ratio may be used. The base clock frequency may be changed using a VCO (Voltage Controlled Oscillator). However, the resultant effect depends on which sort of oscillation circuit is used for a VCO. For example, if a crystal having the highest frequency stability is used, the frequency may be modified by changing the VCXO (Voltage Controlled Xtal Oscillator). However, the ratio of frequency change possible is on the order of only 0.4%. For avoiding the resonance, the change ratio of at least 5% is needed, as previously mentioned. Thus, should this method be used, it is necessary to use the method in combination with the delay time adjustment technique shown in other exemplary embodiments, specifically, in the exemplary embodiments 4 ff. In case of using a VCO based on dielectric materials or the LC system, desired frequency changes may be achieved with the use of the VCO by itself.

In the following exemplary embodiments 2 and 3, the method of identifying the data rate susceptible to interconnection length resonance, referred to in exemplary embodiment 1, viz., non-recommendable data rate, will be explained.

### Exemplary Embodiment 2

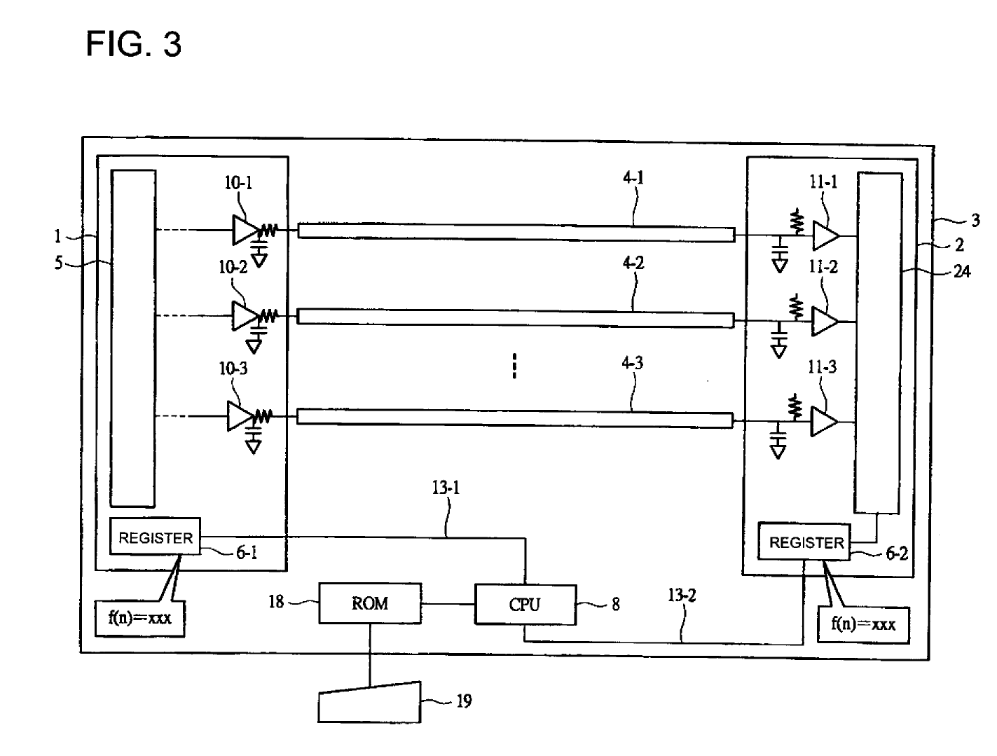

FIG. 3 shows an arrangement of a signal transmission system in exemplary embodiment 2 of the present disclosure.

The signal transmission system in exemplary embodiment 2 is a system of the type for setting the non-recommendable data rate by an input from outside, out of the systems for setting the non-recommendable data rate stated in exemplary embodiment 1.

The arrangement of the signal transmission system in the present exemplary embodiment 2 is analogous with that of FIG. 1. The difference is that the present exemplary embodiment 2 includes a ROM for setting BIOS and an input interface 19 for setting the information for this ROM 18. Exemplary embodiment 2 allows for saving the information regarding the non-recommendable data rate in the ROM 18 by the input interface 19, such as a dip switch.

The CPU 8 reads out data regarding the non-recommendable data rate, saved in the ROM 18, to write the so read out data in the register 6-1 in the memory 1 or in the register 6-2 in the memory controller 2 as the value of the non-recommendable data rate. Based on the information, thus written, the system side exercises control to avoid the non-recommendable data rate.

It is noted that the information regarding the non-recommendable data rate, thus set, may be the direct information, such as the data rate itself, or may also be the information exemplified by the interconnection length or the interconnection propagation delay time. If the latter case, such an equation that will allow for computing the non-recommendable data rate from the information regarding the interconnection length or the interconnection propagation delay time may be afforded to the CPU 8. By so doing, a variety of resonance modes may be coped with based on the sole information item. An equation for computations, as typical of this sort of the equations, will now be discussed in an exemplary embodiment 3.

### Exemplary Embodiment 3

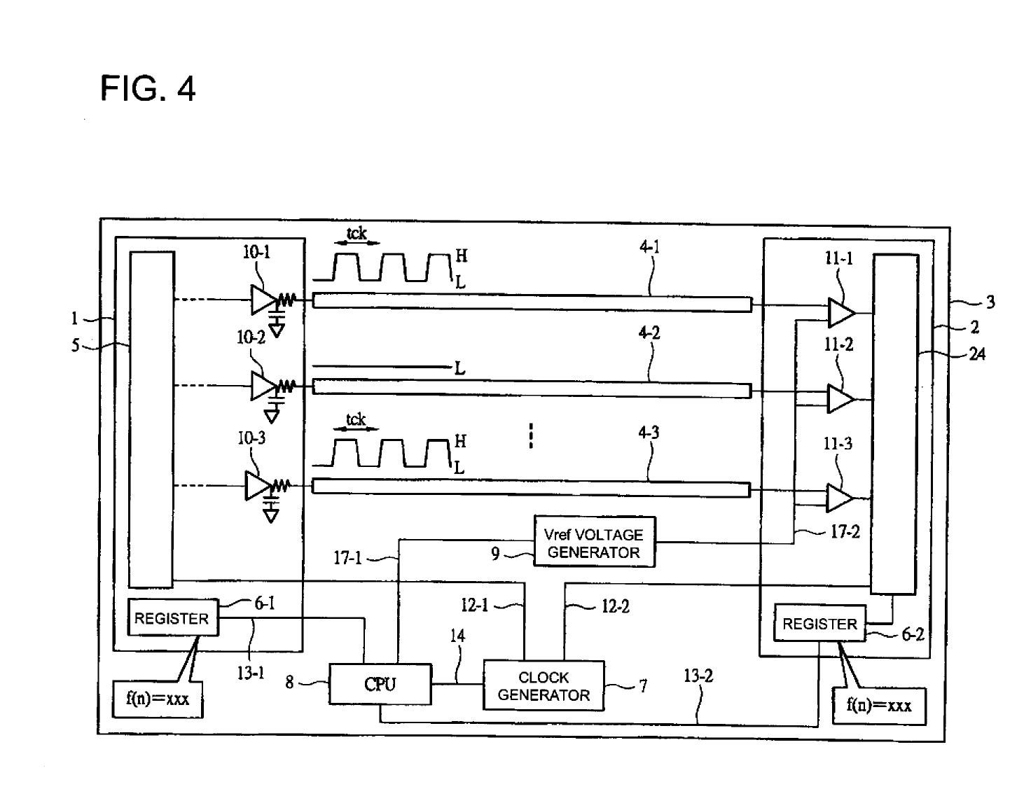

FIG. 4 shows an arrangement of a signal transmission system according to exemplary embodiment 3 of the present disclosure.

The signal transmission system in the present exemplary embodiment 3 is directed to avoiding the interconnection length resonance ascribable to the crosstalk noise with the aid of the technique of setting the non-recommendable data rate discussed in exemplary embodiment 1. Specifically, the signal transmission system in the present exemplary embodiment provides a means for identifying the non-recommendable data rate for avoiding the crosstalk related interconnection length resonance.

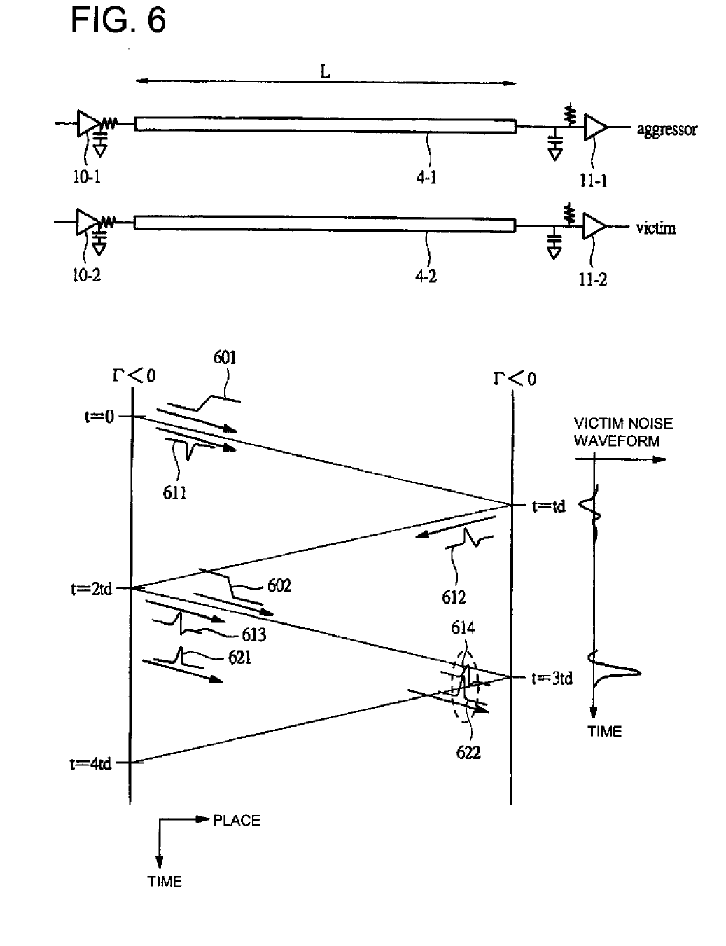

Before proceeding to explanation of the present exemplary embodiment, the principle of generation of the interconnection length resonance ascribable to the crosstalk noise will be explained with reference to FIG. 6.

FIG. 6 shows the relationship of the signal propagated on a signal interconnection and the crosstalk with respect to time and sites as plotted by a grid line drawing method. Suppose that a waveform, rising at time t=0, is transmitted on the signal interconnection 4-1 from the driver circuit 10-1 to the receiver circuit 11-1. The cross talk noise, generated at this time on the neighboring signal interconnection 4-2, is now scrutinized. It is assumed that the signal on the signal line 4-2 is fixed at a LOW level, and the propagation delay of the signal through the interconnection line length L is td. It is also assumed that, in this transmission system, the driver circuit and the receiver circuit are each terminated by an impedance matched resistor, viz., by a resistor having the same resistance value as the characteristic impedance of the interconnection. It is noted however that, since parasitic capacitances exist on both of the driver and receiver circuits, the reflection coefficients on both ends of the interconnection become lesser than 0.

It is now assumed that the forward crosstalk coefficient across the signal interconnections 4-1 and 4-2 be a constant less than 0. In this case, a negative-going pulse-shaped forward crosstalk noise 611 is generated on the signal line 4-2 in synchronism with the rise of a rising waveform 601 transmitted at time t=0 from the driver circuit 10-1. This noise increases in proportion to the coupled interconnection length of the signal lines 4-1 and 4-2 until it arrives at the receiver circuit 11-2 at the same time as the rising waveform arrives at the receiver circuit 11-1 at t=td. This noise is again propagated towards the driver circuit 10-2 as a waveform 612 by capacitive reflection at the receiver circuit 11-2. The noise waveform 612 arrives at a time t=2td at the driver circuit 10-2, at which it is transmitted as a noise waveform 613 due to capacitive reflection at the driver circuit 10-2 towards the receiver circuit side. In this manner, a noise such as shown at 614 arrives at the receiver circuit 11-2 at a time t=3td. This noise has a component that is convexed towards the positive side.

It is now assumed that a signal 602, changed over from HIGH to LOW at time t=2td, has been output by the driver circuit 10-1 at time t=2td. A positive-going pulse-shaped noise 621 is generated in synchronism with the fall of the signal 602. In this case, the transition signal 602 arrives at the receiver circuit 11-1 at time t=3td. A forward crosstalk noise 622 of the positive polarity arrives simultaneously at the receiver circuit 11-2. Hence, the noises 614 and 622, which are both positive, overlap each other, with the result that a noise appreciably greater than otherwise is generated. This noise is a sort of the so-called interconnection length resonance noise determined by the relationship between the interconnection propagation delay time (interconnection length) and the signal switching period (data rate).

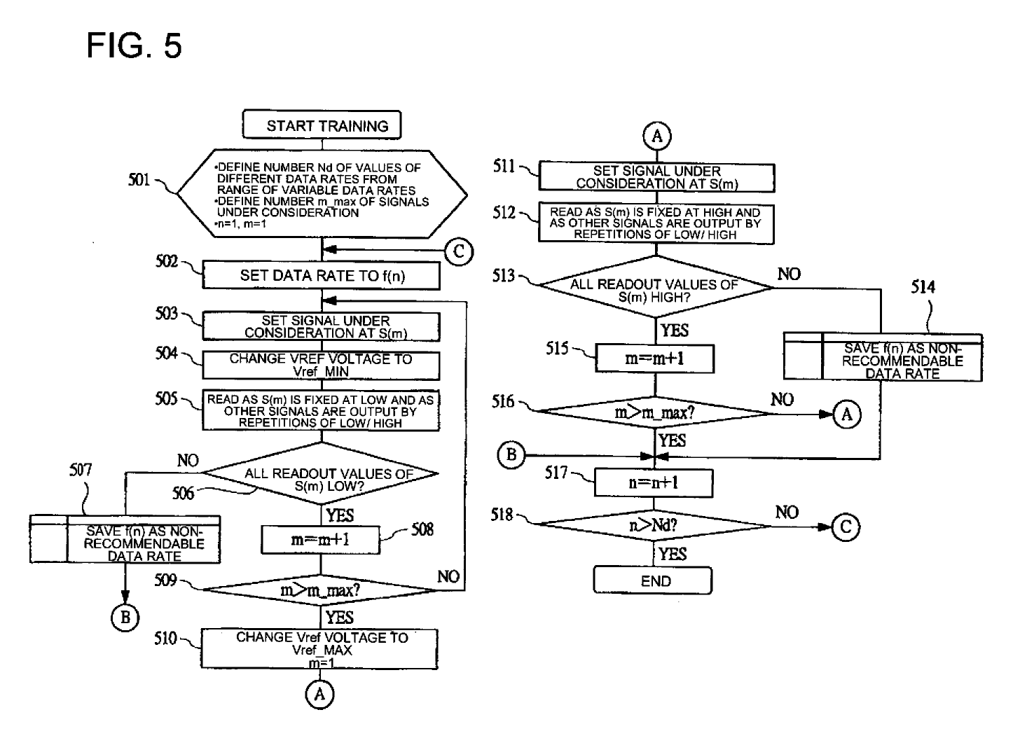

In order for the locally maximum noise not to be generated, it is sufficient that the data rate at which the interconnection length resonance of the crosstalk noise occurs is specified. Referring to FIGS. 4 and 5, a means for specifying such data rate will now be explained.

FIG. 4 shows a signal transmission system for identifying the interconnection length resonance data rate of the crosstalk noise, and FIG. 5 shows a processing flow of the sequence for identifying the interconnection length resonance data rate using this signal transmission system.

The signal transmission system of FIG. 4 features transmitting a reference voltage for the receiver circuits 11-1 to 11-3 of the memory controller 2 from a Vref voltage generator 9, which is a power supply that generates a controllable voltage value. This Vref voltage generator 9 is connected to the CPU 8 via a Vref voltage generator controlling signal interconnection 17-1, while being connected via a Vref feeder interconnection 17-2 to the receiver circuits 11-1 to 11-3.

In the present case, the output level of the Vref voltage may be controlled by a command from the CPU 8. The Vref voltage output level may also be controlled by other methods. The flow of determining the non-recommendable data rate with the use of the signal transmission system of FIG. 4 will now be described with reference to FIG. 5. It is noted that this flow is presumed to be included in a training flow that occurs on power up of the signal transmission system. In a system where the transmission system is dynamically switched during the time the system is in operation, such as in a system where a daughter board is turned on or off in the line live state, the flow is to be executed each time the system is switched.

Initially, the data rates that may be used for the present signal transmission system are numbered from 1 in the order of the increasing frequency. The data rates, thus numbered, are labeled f(n), n being the numbers allocated to the respective data rates. The signals under consideration are similarly numbered and are labeled S(m), m being the numbers allocated to the respective signals. If the signals are data signals, for example, the data are sequentially numbered from DQO.

Then, in a step 501, the number of values of the data rates is defined as Nd, from the range of the variable data rates, and the number of the signals under consideration is defined as m_max. 1 is substituted into each of n and m, as in a step 501. Then, the data rate is set at f(n), and the signal under consideration is set at S(m), as in steps 502 and 503, respectively.

Then, as in a step S504, an output voltage of the Vref voltage generator 9, viz., the Vref supply voltage, is lowered to the minimum allowable value of Vref_MIN, based on, for example, the design statements of the memory controller 2. The minimum allowable value corresponds to the minimum spec value as determined by the design statement for Vref less the DC/AC noise margin of the system. In this state, the signal under consideration is output fixed at LOW, while the remaining signals are output in a data pattern of alternations of LOW and HIGH. The logical value is checked in a READ mode by the memory controller 2 (step 505).

Then, as in step 506, the memory controller 2 checks to see whether or not the readout values of the signal S(m) are all LOW. If the logical values of the signal S(M) are all LOW, the readout has been made correctly. Then, to perform the same operation for the next signal, m is advanced by 1 (step S508), and the steps 503 to 506 are reiterated as long as m does not surpass m_max (step S509). If, in step S509, m has surpassed m_max, similar processing is carried out for the HIGH logic (steps 510 to 516).

If, in a data, obtained halfway, the logical value of S(m) is not LOW (step 506), it is concluded that the noise that crosses Vref_MIN is superposed on S(m) by crosstalk resonance. The data rate f(n) at this time is taken to be the non-recommendable data rate and retained in the registers 6-1 and 6-2 (step 507). In this case, n is advanced by 1 (step S517) to then reiterate similar processing. The above processing is carried out until n surpasses Nd (step 518). The data rates for which crosstalk resonance occurs are listed up as non-recommendable data rates and saved in the registers 6-1 and 6-2.

The above yields a means that identifies the non-recommendable data rates for avoiding the resonance ascribable to crosstalk.

However, the non-recommendable data rate may be estimated from data, such as given interconnection lengths, using an equation for computations, without the necessity of providing the above mentioned training means.

For example, the relationship between the data rate and the interconnection length, for which the jitter (noise along the time direction) is rapidly increased under the phenomenon of resonance due to the forward crosstalk shown in FIG. 6, is given by the following equation:

L=vs·Tdat·N/2 (1)

where L denotes a signal interconnection length [m], vs a speed of an electro-magnetic wave within a printed circuit board [m/s], and Tdat denotes a data period [s], or a so-called IUI (Unit Interval), N being an integer not less than 1. It is sufficient that the data rate that satisfies this equation is avoided. Viz., in this case, the far end crosstalk noise may be prevented from becoming superposed on the reflection noise of the far end crosstalk of the capacitive reflection at the far end of an aggressor signal. Hence, an equation such as one given above is stored in e.g., the CPU 8 to compute the non-recommended data rate from a variety of conditions of the printed circuit board 3.

Meanwhile, as the equations for computations relevant to the resonance phenomenon, the following two equations are also useful.

A first one of the equations expresses the resonance by the backward crosstalk noise. It is necessary to avoid the interconnection length that satisfies the following equation:

L=vs·Tdat·N/2 (2)

Viz., by avoiding the above interconnection length, it is possible to avoid that the near end crosstalk is superposed on the far end crosstalk of capacitive reflection at the far end of the aggressor signal. More precisely, the above equation (2) becomes:

L=vs·(Tdat/2+3Tr/4) (3)

for a case where N=1. In this equation, Tr denotes the rise time of the signal in the signal transmission system.

A second one expresses resonance by the noise of capacitive reflection by the input capacitances of the driver circuits 10-1 to 10-3 of the memory 1 and the receiver circuits 11-1 to 11-3 of the memory controller 2. It is necessary to avoid the interconnection length satisfying the following equation:

L=vs·Tdat·N/2 (4)

Viz., by avoiding the above interconnection length, it becomes possible to avoid interconnection length resonance due to capacitive signal reflection. More precisely, the above equation (4) becomes:

L=vs·(Tdat/2−Tr/4) (5)

for a case where N=1 in the above equation (4). It is sufficient that the relationship between the interconnection length and the data rate, which will satisfy the conditions of the equations (1) to (5), may be avoided by some means or other. It may be advisable, as one such means, that the interconnection length, which will satisfy the above condition, is avoided at the time of designing the printed circuit board.

The technique for solution in a system where the data rate or the interconnection length L may not be changed will now be explained in the following exemplary embodiment 4.

### Exemplary Embodiment 4

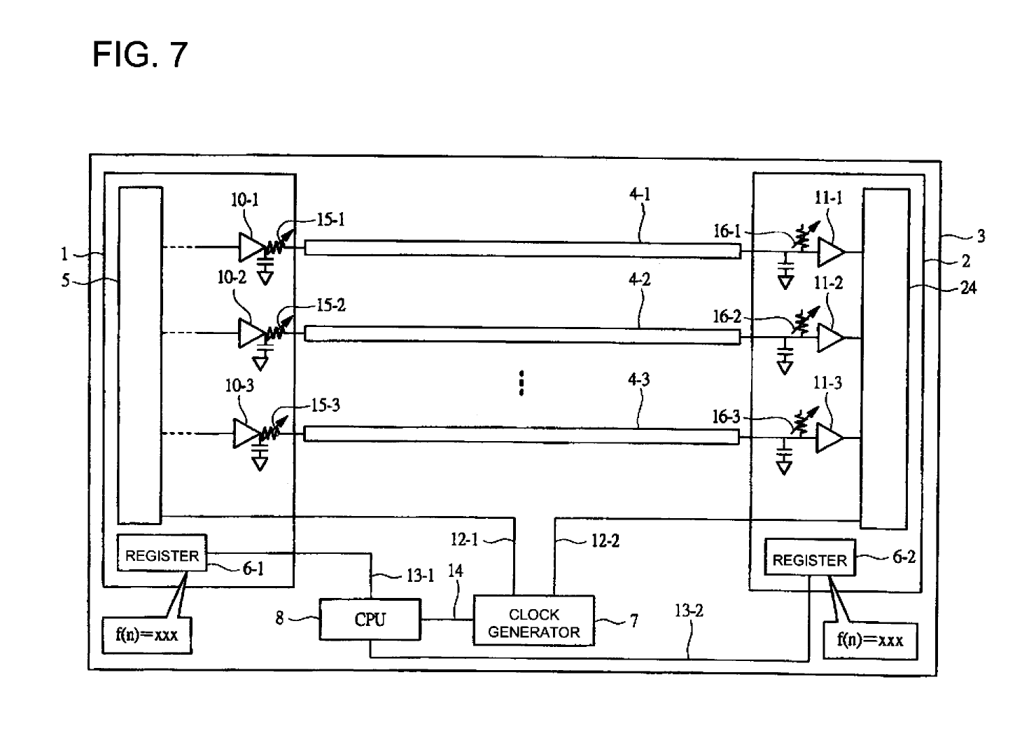

FIG. 7 shows an arrangement of a signal transmission system for exemplary embodiment 4 of the present disclosure.

Initially, an illustrative arrangement of a signal transmission system according to the present exemplary embodiment 4 will be explained with reference to FIG. 7. The arrangement of the signal transmission system of the present exemplary embodiment 4 is analogous with the arrangement shown in FIG. 1. The difference is such that the present exemplary embodiment 4 has the function of changing output impedances 15-1 to 15-3 of the driver circuits 10-1 to 10-3 and input impedances 16-1 to 16-3 of the receiver circuits 11-1 to 11-3 based on the information regarding the non-recommendable data rate stored in the register 6-1 of the memory 1 and in the register 6-2 of the memory controller 2.

By changing the output impedances 15-1 to 15-3 and the input impedances 16-1 to 16-3, the delay time of the capacitive reflection or the phase of the peak voltage of the crosstalk waveform may be modified, thus allowing for avoiding the resonance otherwise caused by changes in the RC delay time. Meanwhile, if the memory 1 is a DRAM, and the DRAM used is of the generation of DDR2 or of later generations, the output impedances 15-1 to 15-3 and the input impedances 16-1 to 16-3 may be adjusted by using the functions of the OCD (Off Chip Driver) and the ODT (On Die Termination).

### Exemplary Embodiment 5

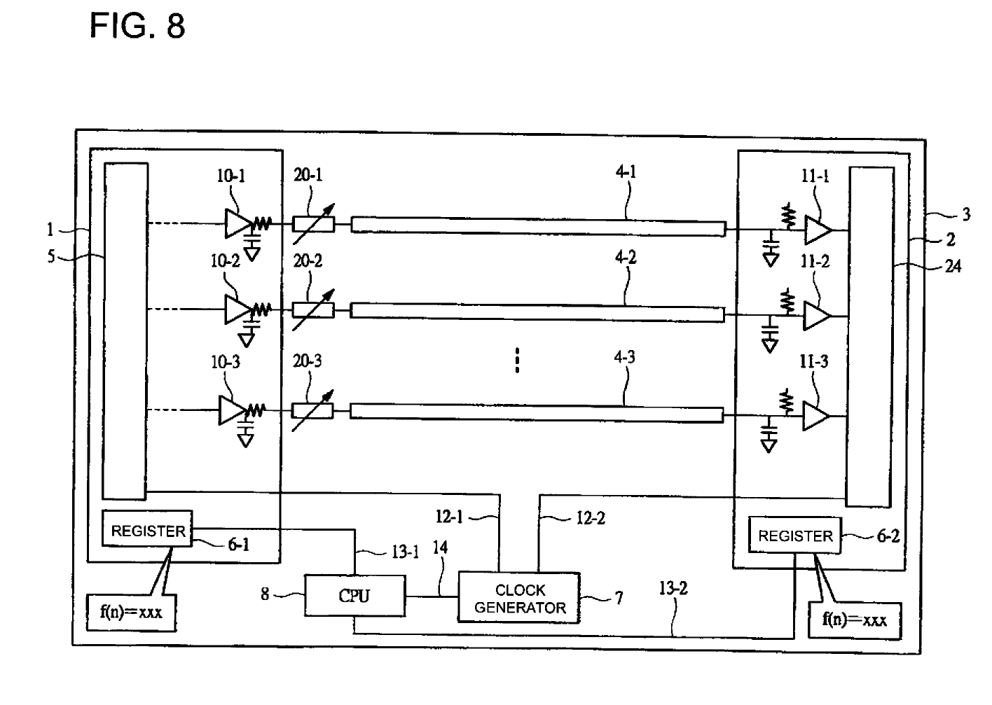

FIG. 8 shows an arrangement of a signal transmission system in exemplary embodiment 5 of the present disclosure.

Initially, an arrangement of the signal transmission system of the present exemplary embodiment 5 will be explained with reference to FIG. 8. The arrangement of the signal transmission system of the present exemplary embodiment 5 is analogous with the arrangement shown in FIG. 1. The difference is that variable delay transmitting components 20-1 to 20-3 are provided halfway on the signal interconnections 4-1 to 4-3.

At the non-recommendable data rate, the propagation delay time may be modified using the variable delay transmitting components 20-1 to 20-3 to avoid the resonance. An illustrative configuration of the variable delay transmitting components 20-1 to 20-3 will be explained in connection with exemplary embodiments 6 and 7.

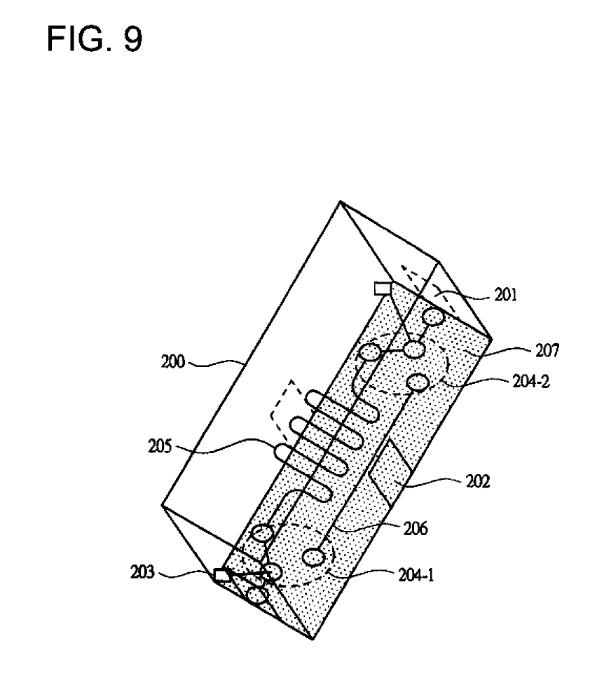

FIG. 9 shows a variable delay transmitting component in a signal transmission system according to exemplary embodiment 6 of the present disclosure.

The present exemplary embodiment 6 shows a means that constructs a variable delay transmitting component of exemplary embodiment 5. FIG. 9 shows the component (MEMS switch type delay time changing component) for a 1-bit signal. Of course, a single component may be constructed for larger numbers of bits.

This component 200 includes MEMS switches 204-1 and 204-2 enclosed therein. The component 200 is featured by the fact that two sorts of transmission paths of different lengths, provided within the component 200, viz., a long interconnection 205 and a short interconnection 206, may be changed over by an external signal from a signal terminal 201 using the MEMS switches 204-1 and 204-2. MEMS is an acronym for Micro Electro Mechanical Systems, and denotes a device composed of mechanical elementary components and electronic circuits integrated on a single silicon substrate, on a glass substrate or in an organic material. In the present instance, the component has enclosed therein a delay switching device 203 for a mobile electrode by, for example, an electrostatic actuator. The mobile electrode may be controlled by the external electrical signal. The component also includes a ground plane 207 enclosed therein and a ground terminal 202 for supplying the ground potential to the ground plane in order to allow for controlling the characteristic impedance of the internal transmitting path of the component 200.

### Exemplary Embodiment 7

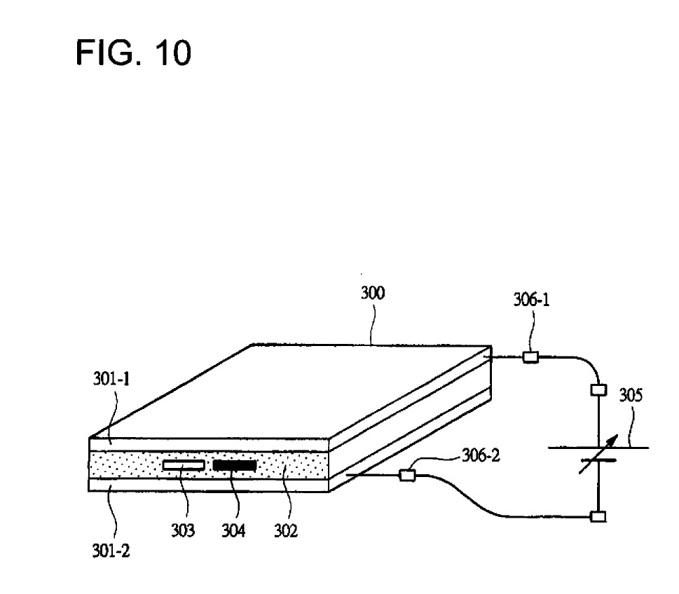

FIG. 10 shows a variable delay transmitting component in a signal transmission system of exemplary embodiment 7.

The present exemplary embodiment 7 provides a means that constructs the variable delay transmitting component shown in connection with exemplary embodiment 5. There is shown in FIG. 10 the component (dielectric constant controlling delay time change component) for a one-bit signal. Of course, a single component 300 may be constructed for larger numbers of bits.

This component 300 includes a thin-film dielectric material 302 and metal electrodes 301-1 and 301-2 that sandwich the dielectric material in-between. A signal interconnection 303 and a ground interconnection 304 are provided inside of a thin-film dielectric material 302. An external voltage of a variable applied voltage type external power supply 305 may be applied to the metal electrodes 301-1 and 301-2 from outside via external terminals 306-1 and 306-2, respectively. As for the thin-film dielectric material 302, the dielectric constant depends on the voltage applied from outside because the characteristic of dielectric polarization is varied with the voltage applied from outside. Viz., the thin-film dielectric material shows DC bias dependency in which the dielectric constant decreases when an external voltage is applied thereto. If a ceramic capacitor equivalent structure is premised, the dielectric constant may be decreased by 5 to 40% on application of 2V. Since the speed of signal propagation is proportionate to a reciprocal of a square root of the dielectric constant of the ambient dielectric material, the speed of the signal passing through it may be increased by a factor of the order of 1.3. Thus, by controlling the voltage applied from outside, it is possible to make fine adjustment of the propagation delay time of the signal passing through the component 300.

### Exemplary Embodiment 8

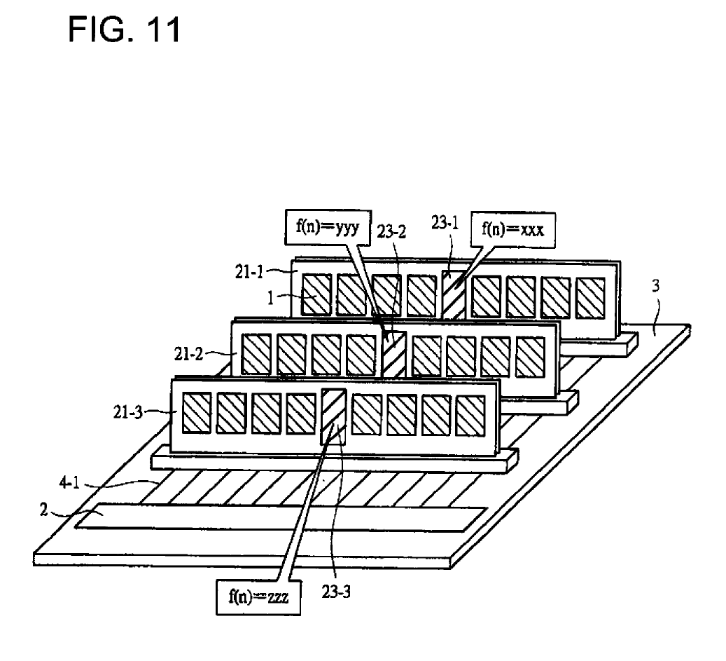

FIG. 11 shows an arrangement of a signal transmission system in an exemplary embodiment 8 of the present disclosure.

In the present exemplary embodiment, a resonance avoiding means, employing a variable delay transmitting component, shown in exemplary embodiment 5, is applied to a memory bus. There is shown here a system that transmits signals from the memory controller 2 to three memory modules 21-1 to 21-3 mounted on the printed circuit board 3. In this system, the non-recommendable data rate is retained not by the register in the memory 1 but by, for example, advanced memory buffers (AMBs) 23-1 to 23-3 of FBDIMM (Fully Buffered DIMM). By so doing, it becomes possible to avoid resonance in signal transmission between the memory controller 2 and the memory 1 or between the advanced memory buffers (AMBs) 23-1 to 23-3.

### Exemplary Embodiment 9

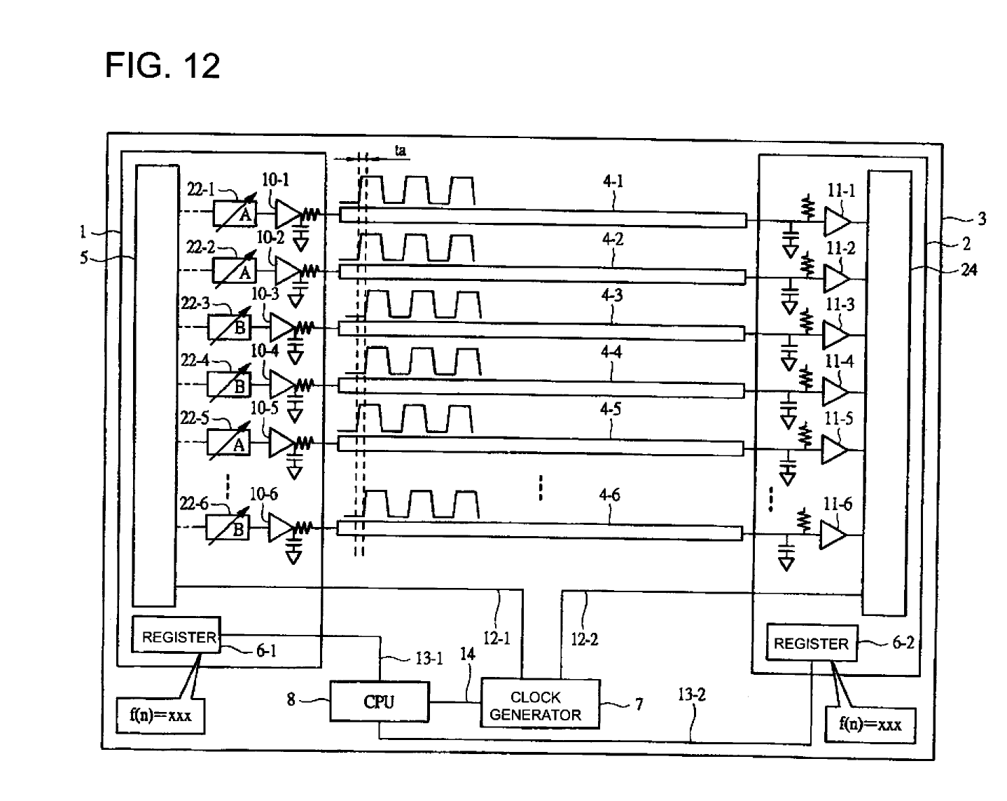

FIG. 12 shows an arrangement of a signal transmission system in an exemplary embodiment 9 of the present disclosure.

The present exemplary embodiment shows a means that avoids the crosstalk resonance. Specifically, the present exemplary embodiment avoids resonance by shifting the phase of the crosstalk on both signal interconnections neighboring to each other.

As the component elements of the present means, it is necessary to provide phase adjustment circuits 22-1 to 22-6 on the side of the driver circuits 10-1 to 10-6 and a phase adjustment function on the side of the receiver circuits 11-1 to 11-6. In crosstalk interconnection length resonance, the amplitude is enlarged by the noise components being in phase with one another. Hence, phase adjustment is made so that the noise components will be out of phase with one another at a data rate susceptible to resonance. As an example, referring to FIG. 12, the phase adjustment circuits 22-1 to 22-6 are provided in a pre-stage (upstream) of driver circuits 10-1 to 10-6 to perform phase adjustment of signal interconnections 4-1 to 4-6. This phase adjustment is performed so that signal interconnections 4-1 and 4-3 will be in phase with each other, signal interconnections 4-2 and 4-4 will be in phase with each other and so forth, whilst signal interconnections 4-2 and 4-3 will not be in phase with each other, signal interconnections 4-4 and 4-5 will not be in phase with each other and so forth. Since in general the crosstalk is most likely to occur under the influence of the neighboring interconnections, the noise may effectively be reduced by shifting the phase of neighboring signal interconnections.

The resonance avoiding effect is prominent in particular in the case of the forward crosstalk noise. For example, the crosstalk noise, superposed on the signal interconnection 4-2, is most likely produced by the signals passing along the signal interconnections 4-1 and 4-3. However, by the operation of the phase adjustment circuits 22-1, 22-2 and 22-3, the rise of the signal on the signal interconnection 4-1 is phase-offset by to from that of the signal on the signal interconnection 4-3. Hence, the local maximum value may not be assumed, with the result that the influence of the interconnection length resonance ascribable to crosstalk may be reduced, with the data rate remaining intact.

The exemplary embodiments, shown so far, may operate effectively by themselves. However, these may also be applied not by themselves but in desired combinations. For example, in the case of changing the clock rate, the rate change width (amount) is small and has only limited effect in case VCXO is used alone. It is more effective to use VCXO in combination with other delay time control technique(s).

In the foregoing, the invention by the present inventor has been described in detail based on its preferred exemplary embodiments. However, the present disclosure is not restricted to these exemplary embodiments and may, of course, be modified in many ways without departing from its purport.

The present disclosure, relating to a semiconductor device, may, in particular, be applied to a semiconductor LSI, such as memory or memory controller, a signal transmission system, comprised of the semiconductor LSI, packaged on a printed circuit board, or to a semiconductor device comprised of the signal transmission system accommodated within a housing. The present disclosure may be optimally applied to a semiconductor device in which a small area and low power supply noise need to be procured in combination.

The entire disclosures of the appended claims are incorporated herein by reference thereto, as preferred modes, respectively. For simplifying the disclosure, duplication of the disclosure is omitted by the incorporation thereof.

In the present disclosure, there are also possible modes as follows.

[Mode 1] A semiconductor device comprises:

a plurality of semiconductor LSIs, and a board which carries the multiple semiconductor LSIs and is adapted to interconnect the multiple semiconductor LSIs via a signal interconnection to constitute a signal transmission system performing signal transmission via the signal interconnection between the multiple semiconductor LSIs carried by the board; wherein

the semiconductor device constitutes a signal transmission system for transmission signals between the multiple semiconductor LSIs carried on the substrate and, to prevent the far end crosstalk noise from being superposed on a reflection noise of a far end crosstalk of capacitive reflection at the far end of an aggressor signal, the interconnection length and the data rate satisfying the following relationship are avoided:

L=vs·Tdat·N/2

where L denotes a signal interconnection length, vs denotes a speed of electro-magnetic wave within the board, Tdat denotes a data period (IUI (Unit Interval)), and N is an integer not less than 1.
[Mode 2] A semiconductor device comprises:

a plurality of semiconductor LSIs, and a board which carries the multiple semiconductor LSIs and adapted to interconnect the multiple semiconductor LSIs via a signal interconnection to constitute a signal transmission system performing signal transmission via the signal interconnection between the multiple semiconductor LSIs carried by the board; wherein

the semiconductor device constitutes a signal transmission system for transmission signals between the multiple semiconductor LSIs carried on the substrate and to prevent near end crosstalk from being superposed on the far end crosstalk of capacitive reflection at the far end of an aggressor signal, the interconnection length and the data rate satisfying the following relationship are avoided:

L=vs·Tdat·N/2

where L denotes a signal interconnection length, vs denotes a speed of electro-magnetic wave within the board, Tdat denotes a data period (IUI (Unit Interval)), and N denotes a natural number.
[Mode 3] A semiconductor device comprises:

a plurality of semiconductor LSIs, and a board which carries the multiple semiconductor LSIs and is adapted to interconnect the multiple semiconductor LSIs via a signal interconnection to constitute a signal transmission system performing signal transmission via the signal interconnection between the multiple semiconductor LSIs carried by the board; wherein

the semiconductor device constitutes a signal transmission system for transmission signals between the multiple semiconductor LSIs carried on the substrate and

to prevent interconnection length resonance ascribable to capacitive signal reflection, the interconnection length and the data rate satisfying the following relationship are avoided:

L=vs·Tdat·N/2

where L denotes a signal interconnection length, vs denotes a speed of electro-magnetic wave within the board, Tdat denotes a data period (IUI (Unit Interval)), and N denotes a natural number.

It should be noted that other objects, features and aspects of the present disclosure will become apparent in the entire disclosure and that modifications may be done without departing the gist and scope of the present disclosure as disclosed herein and claimed as appended herewith.

Also it should be noted that any combination of the disclosed and/or claimed elements, matters and/or items may fall under the modifications aforementioned.

What is claimed is:

1. A semiconductor LSI comprising:
an internal circuit;
a circuit that is coupled to said internal circuit and a signal line which is located outside said semiconductor LSI to transmit a signal to said signal line or receive a signal from said signal line; and
a register that holds information on a specified data rate at which noise or jitter ascribable to signal line length resonance occurs when said semiconductor LSI performs signal transmission with another semiconductor LSI via said signal line.

2. The semiconductor LSI according to claim 1, wherein said register is a nonvolatile device.

3. A semiconductor device comprising a plurality of semiconductor LSIs and
a board carrying said multiple semiconductor LSIs and adapted to interconnect said multiple semiconductor LSIs via a signal interconnection(s); said semiconductor device constituting a signal transmission system that performs signal transmission between said multiple semiconductor LSIs via said signal interconnection(s); said semiconductor device further comprising:
a register that holds information on a specified data rate at which noise or jitter ascribable to interconnection length resonance occurs; wherein
the data rate susceptible to interconnection length resonance is referenced via a nonvolatile device mounted on said board that carries said multiple semiconductor LSIs; the information on the data rate referenced being held by said register.

4. The semiconductor device according to claim 3, wherein
the semiconductor device has a training function that specifies said data rate susceptible to interconnection length resonance during signal transmission between said multiple semiconductor LSIs.

5. The semiconductor device according to claim 4, wherein,
when the resonance during signal transmission between first and second ones of said multiple semiconductor LSIs is to be specified,
data is read out from said first semiconductor LSI;
data is written in said second semiconductor LSI;
a readout data pattern of said first semiconductor LSI is such that, in a
case where data under consideration for specifying the interconnection length resonance is fixed at LOW,
a readout data pattern of data not under consideration of said first semiconductor LSI is a data pattern of repetition(s) of LOW and HIGH;
in a case where a reference voltage of a receiver circuit of said second semiconductor LSI is set at a lowest allowable voltage value, and a data rate at which the write of the data under consideration becomes HIGH while the data rate under variation is identified as the rate susceptible to interconnection length resonance.

6. The semiconductor device according to claim 3, wherein
the semiconductor device constitutes a signal transmission system that performs of signal transmission between said multiple semiconductor LSIs carried by said board; and wherein,
when the information held by a register of said semiconductor LSI is coincident with the data rate about to be used by said signal transmission system, setting of said signal transmission system is modified to inhibit occurrence of said interconnection length resonance.

7. The semiconductor device according to claim 6, wherein
the semiconductor device has a function of adjusting clock frequency of said signal transmission system so that the data rate of said signal transmission system is shifted by at least 5%, in terms of the data period, from the data rate susceptible to interconnection length resonance.

8. The semiconductor device according to claim 6, wherein
the semiconductor device has a function of adjusting an output impedance of a driver circuit in a first one of said multiple semiconductor LSIs or an input impedance of a receiver circuit in a second one of said multiple semiconductor LSIs for the data rate of said signal transmission system susceptible to interconnection length resonance to modify phase of a reflection noise to avoid interconnection length resonance.

9. The semiconductor device according to claim 6, wherein
the semiconductor device includes, as a signal transmission path on said board, a transmission route whose delay time may be modified by an external signal; and wherein
the semiconductor device has the function of adjusting the delay time of said transmission path to avoid the data rate susceptible to interconnection length resonance.

10. The semiconductor device according to claim 6, wherein,
for avoiding the interconnection length resonance ascribable to crosstalk, the semiconductor device includes a function of adjusting output phase of a driver circuit in a first one of said multiple semiconductor LSIs and a function of adjusting input phase of a receiver circuit in a second one of said multiple semiconductor LSIs which is associated with said first multiple semiconductor LSI.

11. The semiconductor device according to claim 9, wherein
a unit is used as said transmission route; said unit including a MEMS switch and two paths having respective different interconnection lengths; said two paths being adapted to be changed over by an external signal.

12. The semiconductor device according to claim 9, wherein,
a unit composed of a thin film dielectric material and pair metal electrodes that sandwich said thin film dielectric material is used as said transmission route; said thin film dielectric material having a signal interconnection and a grounding interconnection enclosed therein; and wherein
a voltage is applied to said metal electrodes to change the speed of signal propagation to avoid interconnection length resonance.

13. The semiconductor device according to claim 3, wherein the interconnection length and the data rate that satisfy the following relationship are avoided:
L=vs·Tdat·N/2
where L denotes a signal interconnection length, vs denotes a speed of the electro-magnetic wave within the board, and Tdat denotes a data period (IUI (Unit Interval), N being an integer not less than 1.

14. A semiconductor apparatus comprising:
a board;
a first semiconductor device which is mounted on said board;
a second semiconductor device which is mounted on said board;
a signal line which is formed on said board to couple said first semiconductor device to said second semiconductor device; and
a register that holds information on a specified data rate at which noise or jitter ascribable to signal line length resonance occurs between said first semiconductor device and said second semiconductor device via said signal line.

15. The semiconductor apparatus according to claim 14, further comprising a central processing unit that performs a training function that specifies said data rate susceptible to signal line length resonance during signal transmission between said first and second semiconductor devices.

16. The semiconductor apparatus according to claim 14, further comprising a central processing unit that performs to change a data rate when said data rate about to be used by said semiconductor apparatus is coincident with said information.

17. The semiconductor apparatus according to claim 14, further comprising a central processing unit that performs to change a frequency of a clock signal which is supplied to said first and second semiconductor devices to avoid said signal line length resonance.

18. The semiconductor apparatus according to claim 14, wherein said first semiconductor device includes a driver circuit coupled to one end of said signal line to transfer data to said signal line and said second semiconductor device includes a receiver circuit coupled to the other end of said signal line to receive said data from said signal line, and an impedance of said driver circuit and receiver circuit is changeable based on said information.

19. The semiconductor apparatus according to claim 14, further comprising a delay time adjustment circuit coupled between said first semiconductor device and said signal line to change a delay time of said signal line based on said information.

20. The semiconductor apparatus according to claim 14, further comprising a central processing unit that reads said information from said register, and a clock generator coupled to said central processing unit, said first and second semiconductor device to provide a clock signal controlled by said central processing unit to said first and second semiconductor device.
